(19) United States
(12) Patent Application Publication
(10) Pub. No.: US 2019/0181326 A1
(43) Pub. Date: Jun. 13, 2019

(54) SUPERCONDUCTIVE LEAD

(71) Applicants: Guy DEUTSCHER, Herzliya (IL); Boaz ALMOG, Rehovot (IL); Mishael AZOULAY, Kfar-Saba (IL)

(72) Inventors: Guy DEUTSCHER, Herzliya (IL); Boaz ALMOG, Rehovot (IL); Mishael AZOULAY, Kfar-Saba (IL)

(21) Appl. No.: 16/207,647

(22) Filed: Dec. 3, 2018

Related U.S. Application Data
(60) Provisional application No. 62/597,519, filed on Dec. 12, 2017.

(51) Int. Cl. H01L 39/12; H01L 39/14; H01L 39/24; H01L 39/16

(52) U.S. Cl. CPC H01L 39/128; H01L 39/16; H01L 39/2461; H01L 39/143

(57) ABSTRACT

A superconducting lead is presented for conducting electrical current to a superconducting device. the superconducting lead comprises first and second sections arranged one after the other along the lead, such that when the lead is brought to the superconducting device, the first and second sections are respectively proximal and distal sections with respect to the superconducting device, the proximal and distal sections being configured such that they differ from one another in at least one of heat conductance and working current.

### FIELD OF THE INVENTION

This invention relates to current carrying leads for supplying high current to a superconductive device, and in particular to a superconductive current lead.

### BACKGROUND OF THE INVENTION

Superconductivity is a phenomenon in which a material completely loses its electrical resistance below a certain temperature known as the critical temperature. Superconducting coils are a common way for achieving strong magnetic fields, and are used in applications such as magnetic resonance imaging (MRI), laboratory magnets, and particle accelerators. Other applications of superconductivity include, for example, magnetometers based on superconducting quantum interference devices (SQUIDs), and magnetic levitation (maglev) devices, such as transport devices or bearings. Such applications need specially designed cryogenics and require a substantial cooling power to operate; both resulting in large initial costs and costly maintenance demands.

Different materials capable of reaching superconducting state are typically classified according to different criteria. One such criterion is based on the critical temperature of the material. High temperature superconductors (HTS) reach the superconducting state at temperatures higher than 77K and thus can be cooled by liquid nitrogen. Low temperature superconductors (LTS) are characterized by critical temperature below 77K and thus require other cooling techniques, such as liquid helium. Most superconducting magnets operate at liquid helium temperature, −268.95 C (4.2K).

High-current leads are typically used to conduct high current from a power source to superconductive devices. Such leads are often an integral part of most superconductive devices such as magnets, motors, generators, superconducting magnetic energy storage (SMES), etc., operating at both liquid helium and liquid nitrogen temperatures. Such leads are typically aimed at providing high current, while enabling relative thermal insulation from the devices' cooled environment. High Temperature Superconductors (HTS), which operate below liquid nitrogen temperature, combine the two desirable properties of current leads: when cooled below 77K such HTS leads provide zero electrical resistance, and most HTS materials provide excellent thermal insulation.

Some of the currently available superconducting current leads include high-critical-temperature (high-T_{c}) superconductors (HTS) such as Bi₂Sr₂Ca₂Cu₃O_{10+X} (BSCCO-2223) and YBa₂Cu₃O₇₋ₓ (YBCO). First generation (1G) HTS current leads are based on composites of silver (or silver alloy) and BSCCO-2223. These are comprised of thin superconducting filaments, having a typical cross section of 10×200 μm², embedded in a silver matrix. Second generation (2G) HTS current leads are manufactured on the basis of coated conductor technology in which Ni—W tapes, stainless steel tapes, or Hastelloy substrates are coated with a thin superconducting layer of YBCO with multiple buffer layers in-between.

In US Patent Application 2010/0298150, a superconducting article having a thick superconductive layer and a high critical current is described being developed by the inventors of the present invention. This publication describes an article which includes a sapphire substrate carrying a superconductive layer of a compound of the formula YBa₂Cu₃O₇₋ₓ (YBCO). In a variant, the sapphire layer has a surface area of at least 10 cm², and critical current of at least 100 A/cm at a temperature of 77K or higher. In one exemplary embodiment, the thickness of the superconductive layer is between 10 nm and 50 nm. In another exemplary embodiment, the thickness of the superconductive layer is more than 600 nm. In preferred embodiment, an Yttrium-stabilized-Zirconia (YSZ) layer and a non-superconductive YBCO layer separate between the superconductive layer and the substrate.

It should be understood that the term “critical current” herein refers to a property of a superconductor structure. The critical current of a structure is the maximal electrical current passing through the structure at which the material of the structure retains its superconductivity. When current above the critical current passes through a material, the material's resistance becomes non-zero and the material is no longer a superconductor (a phenomenon known in the art as “quenching”). Critical current of a structure depends, inter alia, on the structure's material(s), geometry, and temperature.

### GENERAL DESCRIPTION

Both the 1G and the 2G HTS leads described above include metallic parts (silver, Ni—W, stainless steel, Hastelloy substrates) that considerably increase the total thermal conductance through the leads. Therefore, while supplying current to the superconductive device, such leads also carry unwanted heat into the superconductive device. In order to counter this introduction of heat, an increased operation of cryogenic equipment is necessary for keeping the superconducting device at or below a critical temperature thereof.

The thermal conductance of stainless steel is much lower than that of silver. Therefore, the conductive heat leakage in the 2G HTS current leads is substantially lower compared to the 1G leads. However, the conductive substrate of 2G HTS leads (Ni—W, stainless steel, or Hastelloy material) has a finite thermal conductance even at the lowest temperatures, giving rise to a moderate heat leakage even at low temperatures. Moreover, the complex structure of the 2G HTS leads makes them extremely complicated to produce and, thus, highly expensive.

There is therefore a need in the art for a superconducting current lead capable of high current supply while providing efficient thermal insulation.

A further problem that may plague superconductive device is susceptibility to current surges. When a current higher than the device's critical current reaches the superconductive device, the device's resistance becomes non-zero and heat is generated by the electrical current flowing through the no-longer-superconductive device. Such heat might damage the superconductive device. Furthermore, some superconductive devices are kept at a desired temperature by a cryogenic system which includes liquid helium (4.2K). If the current surge is strong enough, the created heat may raise the temperature of the helium above 4.2K and thus cause large quantities of helium to evaporate instantaneously. Such evaporation is likely to cause damage to the cryogenic system and/or to the superconductive device. More specifically, the instantaneous evaporation of liquid helium introduces a large volume of helium gas into the cryogenic system, and therefore causes a sudden rise in pressure that could have destructive effects on the cryogenic system. Moreover, since the device is no longer superconductive, it produces heat due to resistance to electric current. Such heat cannot be dissipated because the cooling power of helium gas is lower than the liquid helium's cooling power. Therefore the produced heat can raise the temperature of the superconductive device, and is likely to destroy the device itself.

There is therefore a need in the art for a superconducting current lead capable of high current supply while preventing currents above a desired value from reaching the superconductive device.

A first aspect of the present invention is aimed at providing a superconducting current lead capable of high current supply to a certain superconductive device and efficient thermal insulation of the device. Such superconducting current lead has a first section proximal to the superconductive device to which current is to be supplied, and a second section distal from the superconductive device. The distal and proximal portions of the lead are in electrical contact with each other. The proximal section has lower thermal conductance than the distal section at low temperatures (for example below 45K), and vice versa at higher temperatures (for example between 45K and 77K), i.e. the distal section has lower thermal conductance than the proximal section at higher temperatures.

The inventors have found that a proximal section having relatively low thermal conductance at low temperatures and relatively high thermal conductance at high temperatures includes a structure having at least a superconductor layer on a dielectric substrate. Furthermore, the inventors have found that a non-limiting example of a distal section having a thermal conductance that is higher at low temperatures and lower at high temperatures than the thermal conductance of the superconductor-on-dielectric structure is a superconductor-on-metal structure or a superconducting-powder-in-tube structure. The superconductor-on-metal structure includes a superconductor layer on a metallic substrate, for example in the form of a lead based on currently available HTS wires or HTS tapes, such as, for example, CryoBlock 2 produced by American Superconductor (AMSC), 2G HTS wire produced by SuperPower Inc., HTS wire produced by Superconductor Technologies Inc. (STI), or HTS tape by Bruker-est. The superconducting-powder-in-tube structure includes a superconductor powder in a tube having metallic strands, for example in the form of a 1G HTS wire produced by AMSC.

The current lead of the present invention, therefore, has a decreased thermal conductance (compared to the currently available current leads) when the proximal section is in a low-temperature region and the distal section is in a higher temperature region.

A second aspect of the present invention relates to a current lead having a current-limiting function for protecting the current lead and/or the superconductive device from an undesirably high electrical current supply to the superconductive device via the lead. This aspect of the invention relates to such property of the current lead as the working current of superconductor structures in two sections of the current lead.

In this connection, it should be noted that for the purposes of the present application, such property “working current” of a superconductor layer is used as referring to a critical current of the superconductor layer corresponding to the highest temperature to which the corresponding lead's section is exposed. It should be understood that as the current lead cannot be generally described by a certain single-value temperature condition, and accordingly cannot be characterized by a well defined critical current value, the working current property is used. For example, if a distal lead section is located in a region in which the temperature is between 45K and 77K, the working current of the distal section's superconductor layer is equal to the critical current value of the superconductor layer at 77K. It should be noted that critical current is a decreasing function of temperature. Therefore the working current of a superconductor layer actually corresponds to the lowest value of the superconductor layer's critical current for a given temperature range.

The current lead includes a first section proximal to the superconductive device to which current is to be directed to, and a second section distal from the superconductive device. The first (proximal) section includes a first superconductor layer having a first working current. The second (distal) section includes a second superconductor layer having a second working current. The properties (materials and/or geometry) of the second (distal) superconductor structure are selected, such that the second superconductor structure has a working current that is considerably lower than what the first working current would be if the first structure were exposed to the same temperature or temperature range as the second superconductor structure. The current lead, when in operation, is connected in series with the superconductive device, such that an electric current is directed through the current lead to the superconductive device. With the above-described configuration of the current lead, when the current passing through the lead exceeds the second working current, the resistance of the second (distal) section of the lead becomes non-zero. This rise in resistance protects the device from undesirably high currents by limiting the current that can reach the superconductive device in at least one of the following manners: (i) the rise in the resistance of the distal section of the lead requires the power supply to supply a voltage higher than the power supply can provide, thereby causing the power supply to shut down; (ii) the rise in resistance causes the temperature of the distal section to rise, and thereby damages the distal section in a manner that prevents the distal section from enabling passage of current therethrough.

This configuration of the current lead enables the current lead to be current limiting (due to the properties of the distal section) without heating the superconductive device when the current flowing through the lead reaches working current of the distal portion's superconductor layer. This is because the proximal section has a considerably higher working current even when heated to reach the temperature of the distal section and therefore is in no risk of becoming resistive when the current flowing through the lead approaches the distal section's working current. In this manner, no heat caused by resistance to current is generated at the proximal section, which is in proximity or in physical contact with the superconductive device.

As will be described further below, the working current of the distal section's superconductor layer may be chosen by selecting an appropriate superconducting material and/or an appropriate geometry/structure of the superconducting material. For example, the distal section of the current lead of a given material initially having certain working current can be configured to have a more reduced working current value by configuring the structure of the current lead within the distal section.

Optionally, the first and second sections of the lead share a common dielectric substrate. Preferably, the first and second sections of the lead are made of the same superconductor, which in the distal section thereof with respect to the device location has a different structure, i.e. is patterned, so as to decrease the maximal critical current thereof.

An aspect of some embodiments of the present invention relates to a superconducting lead for conducting electrical current to a superconducting device, the lead comprising first and second sections arranged one after the other along the lead, such that when the lead is brought to the superconducting device, said first and second sections are respectively proximal and distal sections with respect to the superconducting device, said proximal and distal sections being configured such that they differ from one another in at least one of heat conductance and working current.

In some embodiments of the present invention, said first section has lower heat conductance than said second section at relatively low temperatures; and said second section has a lower heat conductance than said first section at relatively high temperatures.

Optionally, said relatively low temperatures include temperatures approaching 4.2K, and said relatively high temperatures include temperatures approaching 77K.

In a variant, said first section comprises a dielectric substrate coated on at least one side by a first superconductor film.

In another variant, said second section comprises a conductive metallic substrate coated by a second superconductor layer.

In yet another variant, at a temperature Tᵢ, the heat conductance of said first section is equal to the heat conductance of the second section, such that said first section has lower heat conductance than said second section at temperatures in the range between 4.2K and Tᵢ, and said second section has a lower heat conductance than said first section at temperatures in the range between Tᵢ and 77K, Tᵢ being in the range 4.2K≤Tᵢ≤77K.

Optionally, Tᵢ is within a range between 40K and 50K.

In a further variant, said dielectric substrate of said first section is made of sapphire.

In yet a further variant, said first section comprises a superconductive compound of the formula YBa₂Cu₃O₇₋ₓ (YBCO).

Optionally, said first section comprises a superconductive YBCO film on a sapphire substrate.

According to some embodiments of the present invention, said second section comprises a lead section based on a second generation high-temperature-superconductor (2G HTS) wire or tape or a powder of superconductive material in a tube, said tube having at least a metallic strand.

In a variant, said first section further comprises a buffer layer between a dielectric substrate and a superconductor film, said buffer layer being configured to decrease or prevent the diffusion rate of atoms from said substrate to the superconductor film.

In another variant, said first section comprises a dielectric substrate carrying a non-superconductive template layer, and a superconductor film on top of the template layer.

In some embodiments of the present invention, said first section comprises an Yttrium-stabilized-Zirconia (YSZ) buffer layer between a substrate and a superconductive YBCO film, said buffer layer being configured to decrease or prevent diffusion rate of atoms from said substrate to the superconductive YBCO film.

Optionally, said first section comprises a dielectric substrate, a template layer of non-superconductive YBCO, and a YBCO superconductive film on said template layer.

In a further variant, a combination of said superconductor and said dielectric substrate includes one of the following: YBa₂Cu₃O₇₋ₓ layer on a LaAlO₃ substrate; YBa₂Cu₃O₇₋ₓ layer on a SrTiO₃ substrate; YBa₂Cu₃O₇₋ₓ layer on a YSZ substrate; YBa₂Cu₃O₇₋ₓ layer, YSZ buffer, and Si substrate; Tl₂Ba₂CaCu₂O₈ layer on SrTiO₃ substrate.

According to some embodiments of the present invention, said first section comprises a metallic layer deposited on the superconductor film. Said metallic layer may be made of gold or silver, or may be made of a gold-silver alloy.

Optionally, said dielectric substrate is coated on two opposing surfaces thereof by films of said superconductor.

In a variant, said dielectric substrate is a dielectric wire and is coated by said superconductor film on at least two opposite sides or on at least one side of said dielectric wire.

In another variant, said first section of the lead comprises a stack comprising individual strips, each strip comprising said dielectric substrate coated on opposing surfaces thereof by said superconductor film, said blocks being connected in parallel, such that said dielectric surfaces do not touch each other. At least some of said superconductor films of different strips may be in contact with each other.

According to some embodiments of the present invention, said second section has working current lower than a working current that said first section would sport if said first section were at the same temperature or temperature range of said second section, thereby limiting a maximal current flow through the lead when the lead is in a superconducting state.

Optionally, the first and second sections have different material compositions defining said different working current values.

In a variant, the second section is patterned to reduce its working current relative to the working current that the first section would assume if it were at the same temperature or temperature range as the second section.

In another variant, said first section comprises a first dielectric substrate coated on at least one side by a first superconductor film.

In yet another variant, the second section comprises a second dielectric substrate coated on at least one side by a second superconductor film, said second superconductor film having a working current that is lower than the working current that said first superconductor film would have if said first second superconductor film were at the same temperature or temperature range as the second superconductor film. Optionally, said first and second dielectric substrates are parts of a common dielectric structure.

In a further variant, said first and second superconductor films are made of the same superconductor. Optionally, said first and second superconductor films have the same width, and the second superconductor film has a lower thickness than said first superconductor film. Optionally, a region is present on at least one of the first and second sections, in which region the superconductor film thickness grows in a continuous fashion from said lower thickness of said second superconductor film to a maximal thickness of said first superconductor film.

According to a second aspect of some embodiments of the present invention, there is provided a method for manufacturing a structure having a dielectric substrate covered by a superconductor layer, the method comprising: heating the dielectric substrate by placing the dielectric substrate on a row of spaced-apart heated tubes; and coating at least one surface of the dielectric substrate with the superconductor layer.

Optionally, heating the dielectric substrate is achieved by placing the dielectric substrate between two row of spaced-apart heated tubes, the method further comprising rotating the dielectric substrate and said rows of tubes such that the superconductor material reaches the dielectric substrate via spaces between said spaced-apart tubes.

The coating may be achieved by one of: sputtering, laser ablation, and chemical vapor deposition.

According to a third aspect of some embodiments of the present invention, there is provided a method for connecting a superconductive lead to a copper lead, the lead having at least a proximal section comprising a substrate covered by a superconductor layer, the superconductor layer being covered at least in part by a metallic layer, the method comprising pressing a thin metallic foil between the copper lead and the metallic layer. Said thin metallic foil may be made of copper or indium.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1 is a graph illustrating calculated values of thermal conductance of a sapphire crystal and measured values of the thermal conductance of different types of current leads as a function of temperature;

FIG. 2 is a graph illustrating calculated and measured values of phonon heat capacity of sapphire as a function of temperature;

FIG. 3 is a schematic drawing illustrating a low-heat-conductance superconductive current lead of the present invention, connected to a power supply and a superconductive device;

FIGS. 4a-4d are schematic drawings illustrating different architectures of the proximal section of the lead of the present invention;

FIG. 5 is a schematic drawing illustrating a current limiting superconductive current lead of the present invention, connected to a power supply and a superconductive device;

FIGS. 6a-6b are graphs illustrating the dependency of critical current on temperature and the working currents of a single-section current lead and of a two-section current-limiting lead of the present invention;

FIG. 7 is a schematic drawing illustrating an embodiment of the present invention in which the proximal section of the current limiting superconductive current lead is made of a superconductor layer on a dielectric substrate;

FIG. 8 is a schematic drawing illustrating an embodiment of the present invention in which the current limiting superconductive current lead includes two different superconductor layers, each located on a respective dielectric substrate;

FIG. 9a-9c are schematics drawing illustrating different examples of an embodiment of the present invention in which the current limiting superconductive current lead includes a thick layer of a superconductor covering a proximal dielectric substrate and a thin layer of the same superconductor covering a distal dielectric substrate;

FIGS. 10a-11b are schematic drawings illustrating different views of a current limiting superconductive current lead including a dielectric substrate covered by a superconductor layer, wherein the distal section of the superconductor layer is patterned so as to lower a critical current thereof;

FIG. 12 is a schematic drawing illustrating a system for manufacturing a superconductor-on-dielectric structure of the present invention; and

FIG. 13 is a schematic drawing illustrating a connection between a superconductor-on-dielectric structure and a copper lead, according to a technique of the present invention.

### DETAILED DESCRIPTION OF EMBODIMENTS

The invention, in its one aspect, utilizes such properties of a material as thermal conductance and thermal conductivity. Thermal conductivity (k) of a material is a property indicative of the material's ability to transfer heat. Thermal conductance (in Watt/Kelvin) is the quantity of heat that passes in unit time through a plate of particular cross-sectional area and thickness when its opposite faces differ in temperature by one Kelvin.

When multiplied by the temperature difference (ΔT) and the material's cross section (A), and divided by the length (d), the thermal conductivity yields the power transferred through the material (ΔQ/Δt)

$$\frac{Δ Q}{Δ t} = - kA \frac{Δ T}{d} \qquad eq . 1$$

Conductive heat transfer is generally performed by two different mechanisms—free (conductance) electrons and lattice vibrations (phonons). In metals, the electric conductivity and heat conductivity are proportional to each other; the ratio being the temperature multiplied by the Lorenz number (Wiedemann-Franz law)

$$\frac{k}{σ} = LT \qquad eq . 2$$

where k and σ are the thermal and electrical conductivities, respectively, and L=2.45×10⁻⁸ [WΩ/K²] is the Lorenz number.

At low temperatures, the electric conductivity saturates to a finite value due to impurities, and the electronic thermal conductivity decreases linearly with temperature. The second contribution to the thermal conductivity comes from scattering of lattice vibrations (or phonons). In the simplest approximation, given by Debye, the phonon thermal conductivity is given by

k=⅓Cvl eq. 3

where C is the phonon heat capacity, v is the sound velocity and l is the mean free path. The mean free path (d) increases at low temperature; however, it is limited by the sample thickness below a certain temperature. The phonon heat capacity (C) is proportional to T³ at low temperatures and thus causes the phonon thermal conductivity to drop sharply (proportionally to T³).

In metals, the dominant contribution to the thermal conductivity at low temperatures will come from the conductance of electrons. On the other hand, in dielectric materials (such as sapphire, for example), the only contribution will come from phonons.

The inventors have shown that since the phonon thermal conductivity decays strongly with temperature (proportionally to T³), it would be advantageous to use current leads with a dielectric substrate for directing current to a superconductive device at low temperatures, since at low temperatures, the dielectric's thermal conductivity is lower than the thermal conductivity of metals.

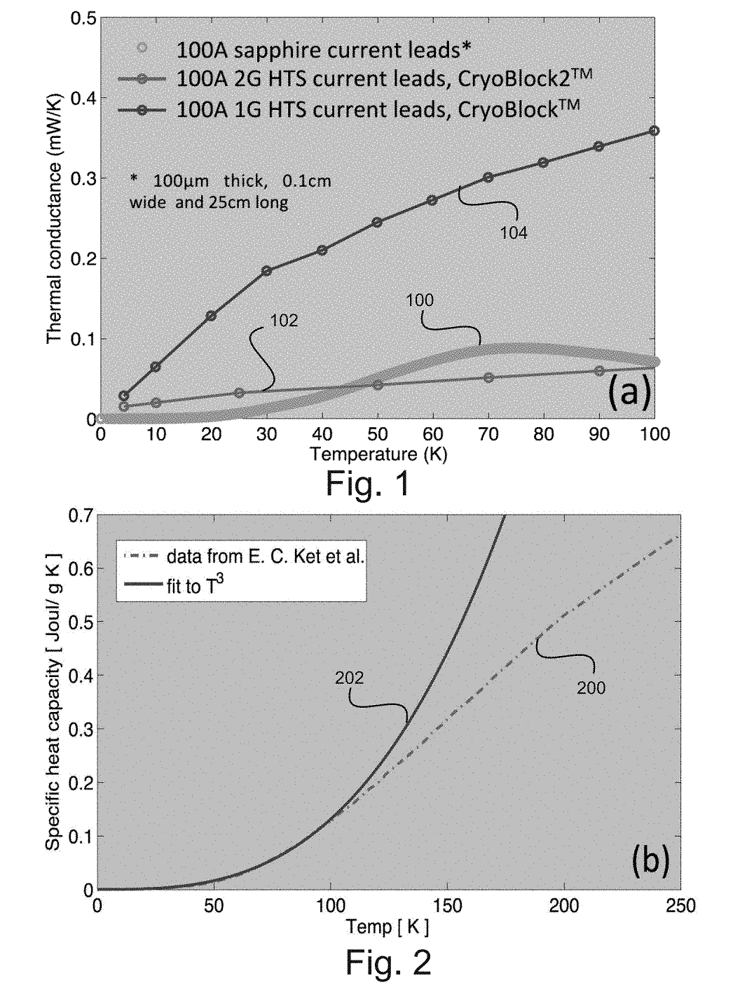

Referring to FIG. 1, the inventors have calculated the temperature dependent dielectric thermal conductance of a 100 μm-thick, 0.1 cm-wide and 25 cm-long sapphire crystal, assuming that the phonon mean free path is thickness-limited. The calculated result is summarized by line 100. The calculation follows the work of Burghartz and Schultz [Burghartz and Schultz, “Thermophysical properties of sapphire AlN and MgAlO down to 70K”, Journal of Nuclear Materials, pp. 212-215, 1065 (1994)] and includes contributions from different phonon scattering mechanisms: Umklapp processes, impurities and boundary phonon scattering. To calculate the sapphire's thermal conductance, the inventors used the sapphire's phonon heat capacity shown in FIG. 2. Below the temperature of 20K, values of the phonon heat capacity of sapphire measured by Kerr et al. [E. C. Kerr, H. L. Johnston, and N. C. Hallett, “Low Temperature Heat Capacities of Inorganic Solids.’ III. Heat Capacity of Aluminum Oxide (Synthetic Sapphire) from 19 to 300° K”, Journal of the American Chemical Society 72, 4740 (1950)] were used (as shown in line 200). Below 20K, the phonon heat capacity was calculated by using the Debye approximation (i.e. C decaying proportionally to T³) as indicated by line 202.

The results reveal the following facts. At temperatures below ˜40K the thermal conductance drops sharply. Around 77K the thermal conductance exhibits a maximum with values as high as 0.09 mW/K, typical of metals having similar dimensions. Comparing the thermal conductance of the sapphire crystal (line 100) to the thermal conductance of the two samples of current leads commercially available from AMSC, one being a 100 A 2G HTS Cryoblock 2 current lead having a thickness of 100 μm, a width of 1 cm, and a length of 25 cm (line 102) and the other being a 100 A 1G HTS Cryoblock current lead by AMSC of the same thickness, width and length (line 104), the inventors have found the following: below 45K, the thermal conductance of the sapphire crystal is lower than the thermal conductance of the 1G and 2G HTS leads; above 45K the 2G HTS lead has lower thermal conductance than the sapphire crystal and the 1G HTS current lead.

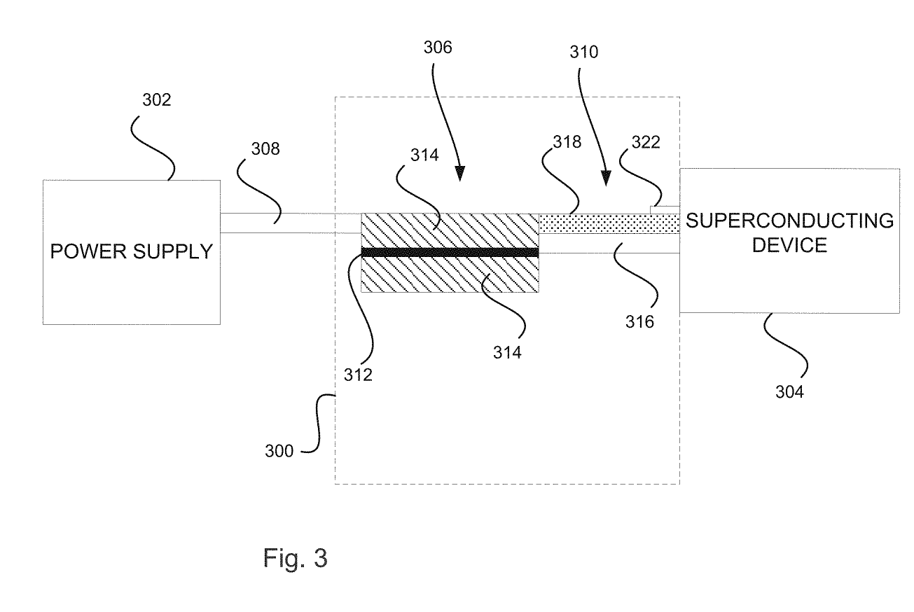

Referring now to FIG. 3, there is illustrated an example of a current lead 300 of the present invention, connected (in series) to a superconductive device 304. Also provided is a power supply 302. The current lead 300 of the present invention is a low-heat-conductance superconductive current lead and is used for conducting high current from the power supply 302 to the superconducting device 304, while providing low heat conductance to the superconductive device 304.

The current lead 300 is configured as a two-part or two-section structure including a first (distal) section 306 located distally from the superconducting device 304 and configured for receiving current from the power supply 302 (either directly or via an outer lead 308), and a second (proximal) section 310 located proximally to the superconducting device 304, and configured for directing the current thereto.

Generally, such a two-section current lead structure has proximal and distal sections of different properties. In the present example, these different properties relate to heat conductance of the lead sections: the proximal section 310 has lower heat conductance at relatively low temperatures and higher conductance at relatively high temperature, while the distal section 306 has opposite properties. These properties are defined by material compositions at the proximal and distal sections.

Turning back to FIG. 3, the proximal section 310 includes a dielectric substrate 316 covered by a superconductor layer (or film) 318. According to a non-limiting example, a distal section 306 having the above-defined heat-conductance-related properties includes a metallic substrate 312 (for example Ni—W, stainless steel, or Hastelloy material) covered by one or more layers 314 of superconductor (such as YBCO, for example). The distal section 306 is preferably a 2G HTS lead, as described above. It should be noted that other structures that are not limited to such superconductor-on-metal structure may respond to the heat-conductance-related properties, and may be used as the distal section 306. Another structure that may, for example, be used in the distal section 306 is the superconducting-powder-in-a tube, as explained above. The superconductor layers of the distal section 306 and of the proximal section 310 are in electrical contact with each other.

In a variant, the dielectric substrate 316 of the proximal section 310 is made of sapphire, and the superconductor of the distal layer 318 is YBCO, as described in an example of US Patent Application 2010/0298150. In some embodiments, a buffer layer of Yttrium-stabilized Zirconia (YSZ) is deposited between the superconductor 318 (YBCO) and the sapphire substrate 316. It should be noted that other arrangements of superconductor/dielectric-substrate structures can be used to yield the current lead of the present invention, for example: YBa₂Cu₃O₇₋ₓ layer on a LaAlO₃ substrate; YBa₂Cu₃O₇₋ₓ layer on a SrTiO₃ substrate; YBa₂Cu₃O₇₋ₓ layer on a YSZ substrate; YBa₂Cu₃O₇₋ₓ layer grown on YSZ buffer and coating a Si substrate; Tl₂Ba₂CaCu₂O₈ layer on SrTiO₃ substrate; etc.

One or more low-resistance electrical contacts (322) between the superconductor layer 318 and the superconductive device 304 may be achieved using in-situ deposition of metal (possibly gold or silver). The metal should have low resistance in order to minimize the heat created in the metallic contacts. In the example of the YBCO/sapphire combination, the inventors have measured that the proximal section 310 having a width of 1 cm, can typically carry a supercurrent of more than 1500 A below 66K. An exemplary manner of fabricating the proximal section 310 may be that described in the above-indicated US Patent Publication 2010/0298150.

Preferably, the distal section 306 is subjected to a temperature (or temperature range) above a predefined temperature (for example, 45K, or a certain temperature in the range between 40K-50K), while the proximal region 310 is subjected to a temperature (or temperature range) below the predefined temperature. The predefined temperature is selected according to the properties of the distal and proximal sections, in order to provide a decreased thermal conductance of the lead 300. This embodiment provides for decreased thermal conductance of the lead 300 compared to single-section current leads, since a 2G HTS lead has lower thermal conductance than sapphire above the predetermined temperature (e.g. 45K), while the sapphire based HTS lead has lower thermal conductance than a 2G HTS lead below the predetermined temperature (e.g. 45K), as has been found by the inventors and described above with reference to FIG. 1. It should be noted that though the calculation of line 100 of FIG. 1 was made for a sapphire substrate alone, the same line 100 is a good approximation (with less than 10%) to the thermal conductance of a HTS lead based on sapphire. This is because the thermal conductance of a thin (˜1-5 μm) film 318 of many superconductors (such as YBCO) is at least two orders of magnitude lower than that of the much thicker substrate 316. In a preferred embodiment of the invention the distal section 306 is in the region at which the temperature (or temperature range) is between 45K and 77K, since not far above 77K most high-temperature superconductors become resistive.

It should be noted that the above-defined predefined temperature of 45K is only an example that applies only to a lead 300 in which the substrate 316 of the proximal section 310 is made of sapphire. Other dielectric materials may behave differently than sapphire, each having a different temperature Tᵢ above which the dielectric substrate 316 of distal section 306 has a lower thermal conductance than the current lead of proximal section 310. Therefore, depending on the specific material choice for the substrate 316, the distal section 306 is preferably in the region at which the temperature is above Tᵢ, and the proximal section 310 is preferably in the region at which the temperature range is below Tᵢ. As indicated above, this temperature Tᵢ is that at which the two different sections (proximal and distal sections with respect to a superconductive device) of the common current lead have the same heat conductance, while at opposite sides of this temperature the heat conductance of the two sections are different.

An important figure of any current lead for low temperature high current devices is the conductive heat leakage, \dot{Q}, in a relevant temperature range, e.g. 4.2K-64K. This can be calculated by integrating Eq. 1 over those temperatures:

$$\dot{Q} = \frac{A}{l} {\int }_{4.2 K}^{64 K} k ( T ) dT \qquad eq . 4$$

where A and l are the cross sectional area and length of the current lead, respectively, and k(T) is the thermal conductivity.

The heat leakage from the current leads includes the relative contributions (according to the cross section) of the HTS strip and the inclosing casing which is usually made of epoxy (for example, G10 epoxy).

In Table I below, the conductive heat leakages of different 100 A current leads are shown: 1) YBCO/Sapphire lead based upon US 2010/0298150 2) CryoBlock™, based on 1G HTS wire from American Superconductors (AMSC) 3) CryoBlock2™, based on 2G HTS tape from AMSC and 4) SF4050, based on 2G HTS tape from SuperPower®. The coated sapphire current leads are at least 3 times better (less leakage) than the best 1G and 2G HTS current leads in the temperature range between 4.2K and 64K.

TABLE I
The conductive heat leakage of 100 A HTS current leads on sapphire
and 1st and 2nd generation HTS wires

| 100 A Current lead based on: | Conductive heat leakage* |
|---|---|
| CryoBlock ™(AMSC 1G BSCCO wire) | 14.4 mW |
| CryoBlock2 ™(AMSC 2G HTS tape) | 8.4 mW |
| SuperPower ® (SF4050 2G HTS tape)** | 6.4 mW |
| Sapphire leads (100 μm thick, double side | 1.95 mW |
| coated) | |

Here, *relates to conductive heat leakage in a temperature range 4.2 K < T < 64 K including leakage from an epoxy (G10) casing, 25 cm long; and
**relates to data based on the manufacturer data of the bare HTS wire including an epoxy shielding, as found in the manufacturer's website: http://www.superpower-inc.com/system/files/SP_Current+Leads_2010_v1.pdf.

The inventors have found that a major advantage of superconducting films on suitable dielectric substrates, such as sapphire, is their high quality, specifically high superconductor critical currents. Current leads made of such films have a higher current capacity per unit width than conventional HTS current leads, and thus a lower heat leakage for a given carried current. In fact, the inventors have achieved a current capacity of 500 A per cm width in a single sided current lead on sapphire at 77K. A double-sided lead would give twice this current capacity at 77K—i.e., 1000 A/cm width. This current capacity is substantially higher than the 250-350 A/cm width achieved by HTS tapes on metallic substrates.

In Table II below, a comparison is made between the conductive heat leakage of a commercial 1 kA 2G HTS current lead by HTS-110 (according to the manufacturer specifications) and the calculated conductive heat leakage of a YBCO-on-sapphire lead between the temperatures of 4.2K and 64K. The YBCO-on-sapphire lead is clearly superior to the 2G commercial lead, with about an order of magnitude lower heat leakage.

TABLE II
The conductive heat leakage of a single 1 kA current lead

| 1 kA Current lead based on: | Conductive heat leakage* |
|---|---|
| CryoSaver ™(1 kA HTS-110 2G HTS tape)** | 142.5 mW |
| YBCO on Sapphire leads (1 kA, 100 μm thick, | 19.5 mW |
| double side coated) | |

Here, *relates to conductive heat leakage in a temperature range 4.2 K < T < 64 K including leakage from an epoxy (G10) casing, 25 cm long; and
**relates to data based on the manufacturers' data found in the HTS-110 CryosaverTM brochure, at http://www.hts110.co.nz/wp-content/uploads/2008/11/hts-110currentleads1.pdf

As shown above in FIG. 1, and Tables I and II, the use of a superconductor-on-dielectric in the proximal section 310 of the lead is advantageous for its low heat conductance and low heat leakage at low temperatures (for example, below 45K). Therefore, as explained above, the combination of a distal superconductor-on-metal section 306 (preferably a 2G-HTS lead) with a superconductor-on-dielectric proximal section 310 takes advantage of the low thermal conductance of the 2G HTS section at higher temperatures with the low thermal conductance of the superconductor-on-dielectric at lower temperatures, and provides a low thermal conductance for a large range of temperatures. For a large range of temperatures (for example, between 4.2K and 77K), the thermal conductance of the two-part current lead 300 is lower than the thermal conductance of a lead which only includes a 2G HTS structure or of a lead that only includes a superconductor-on dielectric structure.

Furthermore, it is known that production of some dielectric substrates (especially, sapphire substrates) having a length of more than 10 cm may be technically difficult and expensive. Therefore, the combination of the proximal superconductor-on-dielectric section 310 with the distal superconductor-on-metal section 306 enables the manufacture of a lead 300 of a desired length, without incurring expenses related to the fabrication of a long substrate 316. In a non-limiting example, the current lead 300 has a length of 30 cm. In such configuration, the proximal section 310 may have a length between 10 and 20 cm. In a particular, non-limiting, configuration of the present invention, each of the proximal and distal sections has a length of about 15 cm.

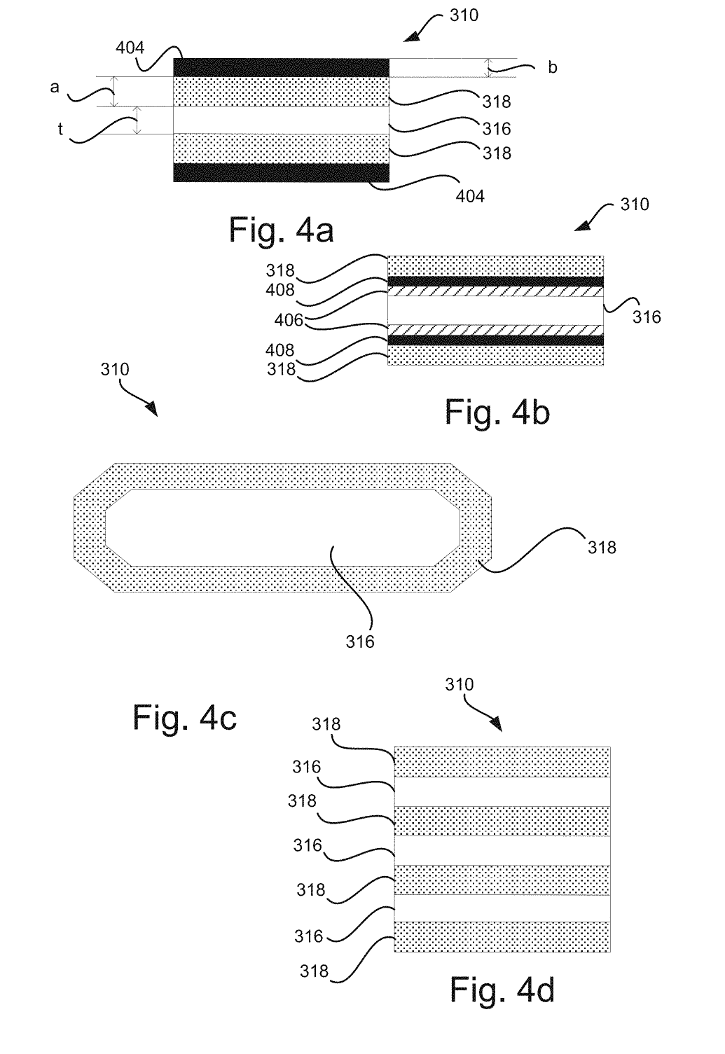

Referring now to FIGS. 4a-4d, different architectures of the proximal section 310 of the lead 300 are illustrated.

In FIG. 4a, a side cross sectional view of the proximal section 310 is shown. The substrate 316 is coated on both sides by a superconductor layer 318. Optionally the thickness of the substrate is in the range between 100 μm and 500 μm. Preferably, the substrate 316 has a thickness t of 0.1 mm. According to a non-limiting example, the substrate 316 is an r-cut sapphire single crystal.

Each superconductor layer 318 has a thickness a chosen to enable the superconductor 318 to have a desired (typically high) critical current. It should be noted that the critical current of a superconductor grows with the cross sectional area thereof. Since the cross sectional area is defined as thickness multiplied by width, the critical current grows with the thickness of the layer 318 for a given width of the layer 318. According to a non-limiting example, the thickness a of each superconductor layer 318 is about 1 μm. Optionally, the thickness a is within the range between 1 μm and 5 μm. In a variant, the superconductor layer 318 is a layer of superconducting YBCO.

According to the inventor's measurements, a superconducting YBCO layer 318 having thickness of 3 μm has a maximal critical current of 500 A/cm-width at 77K. This value is tripled at 64K (1500 A/cm-width). Therefore, a single double-sided section as shown in FIG. 4a, having a 1 cm-wide and 3 μm-thick YBCO layer, can carry a maximal current of 3 kA at 64K. At lower temperatures (for example, below 45K), this maximal critical current is even higher.

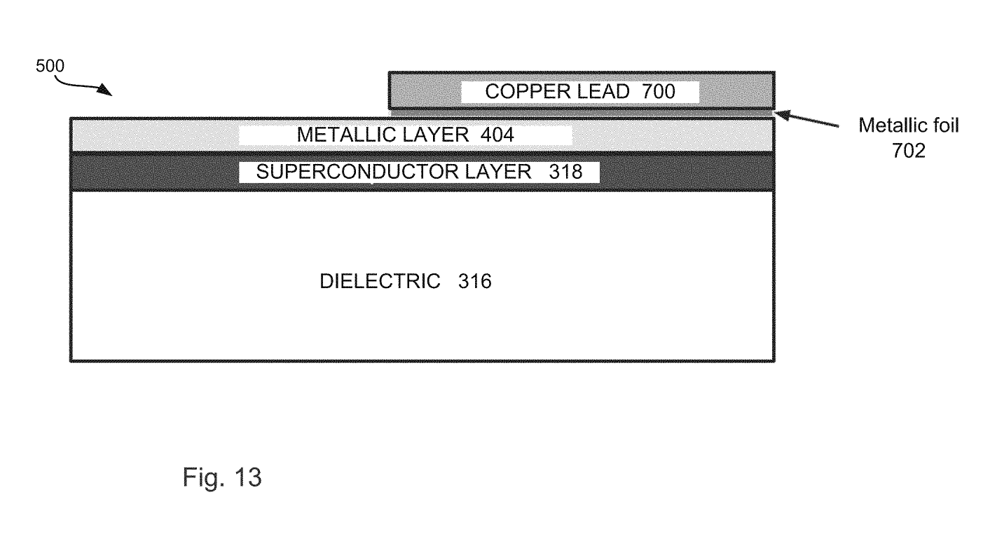

According to some embodiments of the present invention, at least one of the outer surfaces of the superconductor layers 318 is coated by a metallic layer 404. The metallic layer 404 may protect the superconductor from humidity and may prevent degradation of the superconductor layer 318 due to oxygen depletion. Optionally, the metallic layer 304 may be used in the provision of an electrical connection between the proximal section 310 and the superconductive device 304, as illustrated in FIG. 13 and explained below. The metallic layer 404 may be deposited in-situ during the fabrication of the proximal section 310.

Optionally, the metallic layer 404 is made of a low-resistance metal (for example having a resistivity below 10μΩ-cm), such as silver or gold. Such a low-resistance metallic layer 404 may also serve as a shunt in case the superconductor layer 318 becomes resistive, decreasing the current passing through the superconductor layer 318 during a quench, and therefore protecting the superconductor layer 318 from heat-generated damage.

Alternatively, the metallic layer 404 may be resistive, for example made of an Au—Ag alloy. A metallic layer 404 having moderately high resistance has lower heat conductance compared to low-resistance metallic layer. Furthermore, a resistive metallic layer 404 can have a current limiting function. In fact, when the superconductor layer 318 becomes resistive, some of the current will pass through the metallic layer 404. The moderately high resistance of the metallic layer 404 coupled with the high current passing therethrough will require the power supply to supply a voltage higher than the power supply can provide, thereby causing the power supply to shut down.

In an exemplary embodiment of the present invention, the thickness b of the metallic layer 404 is in the range between 10 nm and 500 nm. Preferably, the metallic layer 404 is thin (about 100 nm), such that its contribution to the heat conductance is much smaller that that of the superconductor layer 218 and/or the dielectric substrate 316.

In FIG. 4b, a side view of an embodiment of the proximal section 310 is shown. According to this specific non-limiting example, a dielectric substrate 316 is covered on both sides by buffer layers 406. A superconductor layer 318 is placed on the outer surface of each buffer layer 406. The buffer layers 406 decrease or prevent the diffusion rate of atoms, for instance aluminum atoms, from the substrate 316 to the superconductive layer 318. In a non-limiting example, the buffer layers 406 are made of YSZ, each YSZ layer 406 having a thickness within the range between 50 nm and 200 nm.

Optionally, a template layer 408 is located between the substrate 316 and the superconductor layer 318, or between the buffer layer 406 (if present) and the superconductor layer 318. Optionally, the structure of the template layer 408 fits that of the buffer layer 406 (or of the substrate 316) more closely than does the structure of the superconductive layer 318. In this manner, the template layer 408 provides an intermediate structure, and allows the growth of thicker superconductor layers 318 than would be grown without the template 408. In exemplary embodiments, the buffer layer 406 is made of YSZ, the superconductive layer 318 is made of YBCO, and a fit between the template layer 408 and the YSZ layer 406 is achieved when the template layer 408 comprises non-superconductive YBCO, for example YBCO with c-lattice parameter greater than 1.175 nm. Exemplary values of c-lattice parameters of template layers are between 1.178 and 1.180 nm, which correspond to x values of the YBCO formula (YBa₂Cu₃O₇₋ₓ) between about 0.8 and about 0.9.

In some embodiments, the value of x in the template layer 408 is constant, and there is a sharp border between the template layer 408 and the superconductive layer 318. In some embodiments, the value of x in the template layer 408 is not constant. For example, in some embodiments the value of x progresses continuously from less than 1 (near the YSZ 406) to about 0.1 (near the superconductor 318). Optionally the template YBCO layer 408 has a c lattice parameter of at least 1.175 nm, and the superconductive layer 318 of YBCO has a c lattice parameter of between 1.1169 and 1.171 nm.

FIG. 4c exemplifies a front cross-sectional view of the proximal section 310. The substrate 316 is a dielectric wire having a polygonal (or alternatively circular) cross section, and interfaces at least at two opposite sides (above and below) thereof (and optionally on all sides) with the superconductor layer 318. For the purposes of this document, the term “wire” refers to a strip with a height/width aspect ratio of at least 4:1. As above, a buffer layer and/or a template layer may be interposed between the substrate 316 and the superconductor layer 318.

In some embodiments, the dielectric substrate 316 is an r-cut sapphire wire, fiber, tape, or ribbon. A non-limiting example of a r-cut sapphire wire is described in US Patent Application Publication No. 2009-0081456 to Goyal, incorporated herein by reference in its entirety. Such substrates are referred herein generally as sapphire wires.

Exemplary dimensions of sapphire wire substrate are as described by Goyal, for example: length larger than width by factor of at least 10, length of between 1 m and 1000 m, thickness of between 50 μm and 400 μm, and width of between 100 μm and 25 cm.

FIG. 4d shows an example of a side cross-sectional view of the proximal section 310. In this example, the proximal section of the lead is in the form of a stack of double sided coated dielectric-substrate/superconductor (e.g. Sapphire/YBCO) strips. The superconductor films of different strips may or may not be in physical contact with each other. According to the inventors' calculations, a stack built from a plurality of 40 250 μm-thick sapphire substrates coated on both sides with 3 μm-thick superconducting YBCO films, such that the stack has a cross section of 1 cm², is able to carry a supercurrent of 120 kA below 66K. This supercurrent is beyond the value required even in the largest scale applications. A buffer layer and/or a template layer may be interposed between each substrate 316 and each of the superconductor layers 318, as described above. It should be noted that the stack may be rigid or flexible, depending on the material properties and the geometry of the substrates 316, the superconductor layers 318, and of the buffer layer(s) and/or template layer(s) if present.

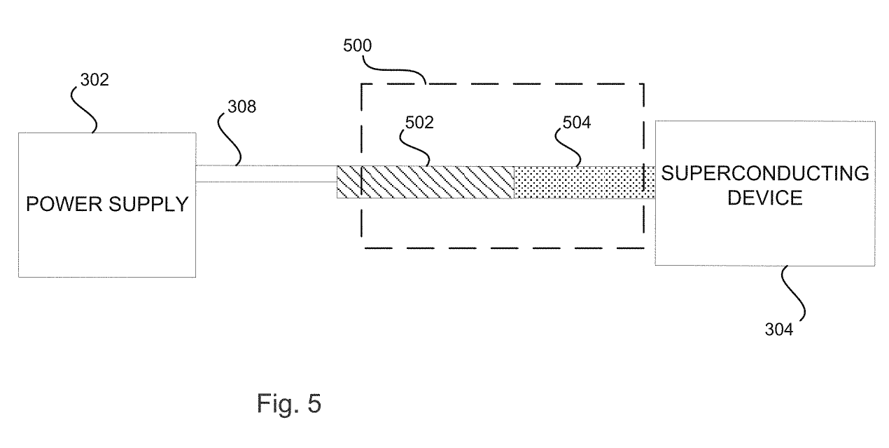

Reference is made to FIG. 5 being a schematic drawing of a current limiting lead for protecting a superconductive device 304 from a current higher than the working current of the device, and therefore from undesirable heating caused by resistance of the superconductive device 304 to such current, when such current is injected through a lead. The current limiting superconductive current lead 500 of the present invention is connected to the superconductive device 304 and associated with a power supply 302. The current limiting lead 500 is a two-section device where the two sections have different properties with respect to a working current. The lead 500 includes a first section 502 distal from the superconductive device 304 to which current is to be directed to, and a second section 504 proximal to the superconductive device 304. When connected to the power supply 302 and the superconductive device 304, the proximal section 504 is in a region having a low temperature range (for example, between 4.2K and 45K) and the distal section 502 is a region having a high temperature range (for example, between 45K and 77K). The high temperature range is typically (but not necessarily) contiguous to the low temperature range, such that the maximal temperature of the low temperature range is equal to the minimal temperature of the high temperature range. The distal section 502 includes a first superconductor layer having a first working current, and the proximal section 504 includes a second superconductor layer having a second working current. The first (distal) superconductor layer has a working current that is considerably lower than what the second working current would be if the second (proximal) superconductor layer were at the same temperature or temperature range as the first (distal) superconductor layer. According to a non-limiting example, the working current of the distal section 502 at the maximal temperature of the high-temperature range is about 1000 A, while for the same temperature the working current of the proximal section 504 is about 1500 A. These values may be achievable, for example, when the proximal and distal sections are each made of a dielectric substrate covered by a superconducting layer. It should be noted that different values of working current of the two sections of the current lead may be achieved by using different material compositions in these sections, and/or different geometries/structures of these sections. For example, the distal section of the current lead having a given superconductive material initially having a certain working current can be configured to have a lower working current value by configuring to the structure of the current lead within the distal section.

In this manner, when the current passing through the lead exceeds the first critical current, the resistance of the distal section 502 of the lead becomes non-zero, thereby limiting the current that can reach the superconductive device, and protecting the device, as well as the proximal section 504 of the lead 500, from undesirably high currents. The current limiting occurs in at least one of the following manners: (i) the rise in the resistance of the distal section 502 requires supply of a voltage higher than the power supply can provide, thereby causing the power supply to shut down; (ii) the rise in resistance of the distal section 502 causes the temperature of the distal section to rise, and thereby damages the distal section in a manner that prevents the distal section from enabling passage of current therethrough.

Furthermore, the provision of the proximal section 504 having a working current considerably higher than the working current of the distal section 502 for the same temperature or temperature range enables the lead 500 to be current limiting without heating the superconductive device, when the current flowing through the lead reaches the working current value of the distal section 502. In fact, even if the proximal section 504 is heated up because of the resistive heating of the contiguous distal section 502, the working current of the proximal section 504 at any temperature within the high temperature range will be higher than or equal to the value that the working current of the proximal section 504 would assume at the temperature (or temperature range) of the distal section. Therefore, the working current of the proximal section 504 at any temperature within the high temperature range will be considerably higher than the working current of the distal section 502. In this manner, there is in no risk that the proximal section 504 becomes resistive when the current flowing through the lead reaches the distal section's working current. Therefore, no heat caused by the material resistance to electric current is generated at the proximal section 504, which is in proximity or in physical contact with the superconductive device 304.

As mentioned above, when the current through the lead reaches the working current value of the distal section 502, heat is created by the current's passage through the resistive distal section 502. Such heat may be detected, enabling the shutting of the current or diverting of the current from the lead, before undesirably high heat and/or current can cause damage to the lead and/or to the superconductive device.

The first and second superconductors are in electrical contact with each other, in order to enable passage of current through the lead 500. The proximal section 504 may or may not be in direct contact with the superconductive device 304. The distal section 502 may be connected to the power supply via an outer lead 308 (such as a copper lead, for example).

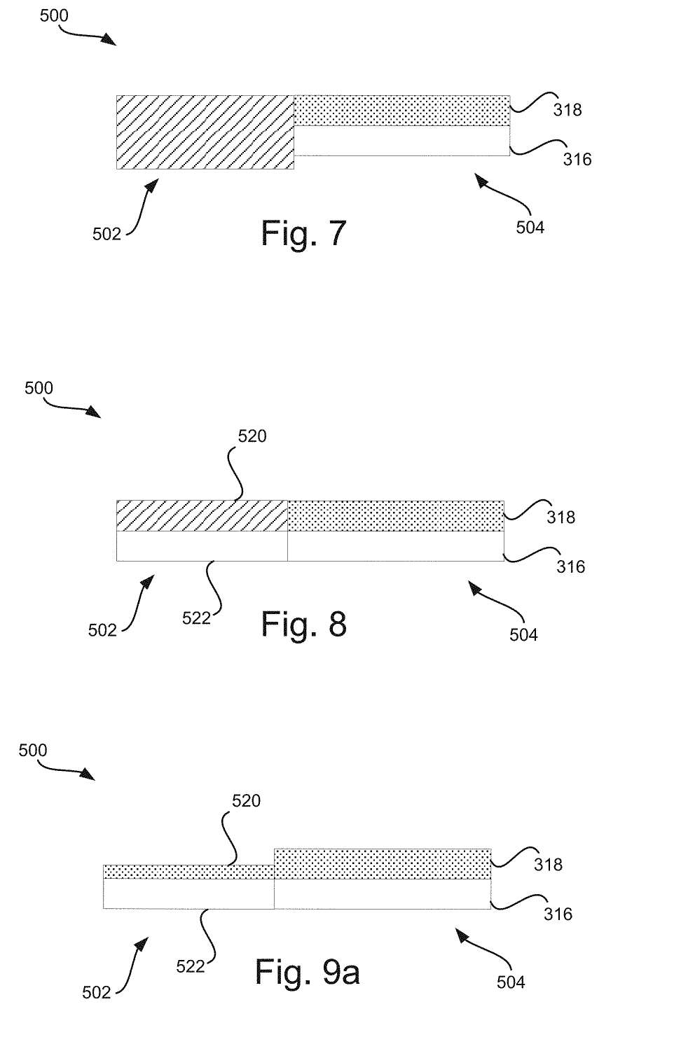

As indicated above, the proximal and distal sections of the current may have different material compositions and/or different geometries/structures such that the distal section 502 has a substantially lower working current as compared to the value that the working current of the proximal section 504 would assume if it were at the same temperature or temperature range as the distal section 502. FIGS. 7-11b illustrate several examples of the implementation of such a two-section current lead of the present invention.

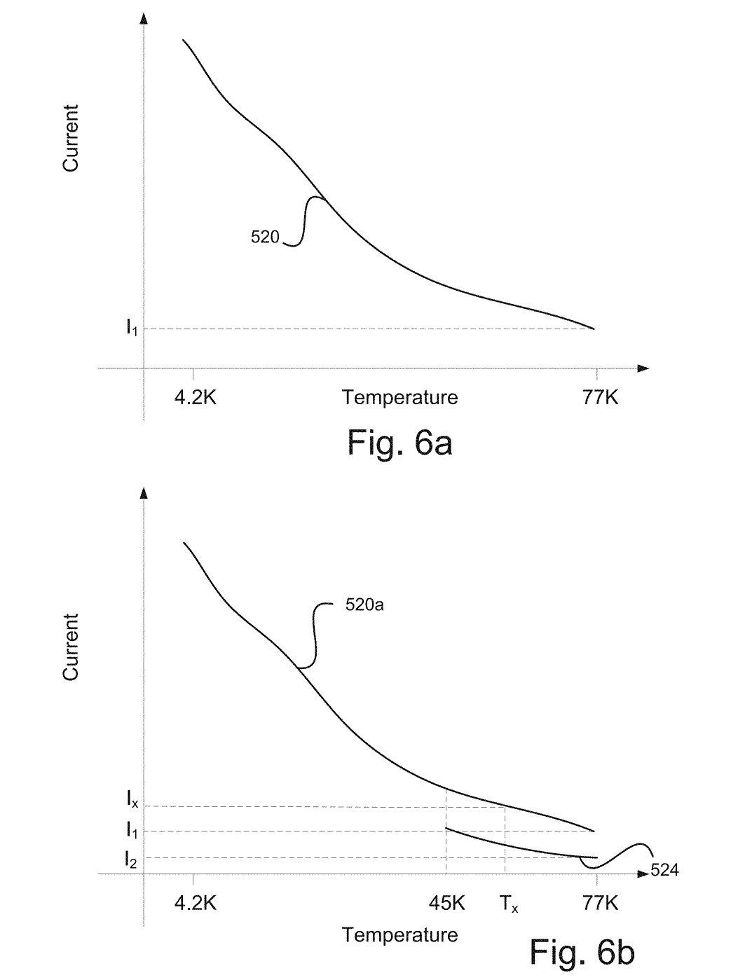

Referring now to FIGS. 6a-6b, FIG. 6a is a graph illustrating the dependency of critical current on temperature for an example of a single-section current lead, as well as the working current of the lead, when at least a portion of the lead is at a temperature of 77K; FIG. 6b is a graph illustrating an example of the dependency of critical current on temperature for an example of a two-section current-limiting lead of the present invention, as well as the working current of the lead portions, for certain temperatures.

In FIG. 6a, a single-section current lead is kept between the temperatures of 4.2K and 77K. The curve 520 illustrates how the critical current of the superconductor layer of the current lead decreases as temperature increases. The working current (I₁) of the single-section lead is the value of the critical current at the highest temperature (77K). If a current above I₁ passes through the single-section lead, the whole lead may quench, and the resulting heat may damage the superconductive device associated to the lead.

In FIG. 6b, an exemplary two-section current limiting lead of the present invention (such as the lead 500 of FIG. 5) includes a proximal section (such as section 504 of FIG. 5) kept in the temperature range between 4.2K and 45K and a distal section (such as section 502 of FIG. 5) kept in the temperature range between 45K and 77K. The proximal section has the same critical current characteristics as the single-section lead of FIG. 6a, as can be seen by the fact that the curve 520a illustrating the critical current curve of the proximal section is identical to the curve 520 of FIG. 6a. The temperature dependence of the distal section's critical current is illustrated by line 524. The distal section is designed such that, the working current I₂ of the distal section is considerably lower than the working current I_{I} that the proximal section would have if the proximal section were exposed to the maximal temperature of the distal section (77K).

Therefore currents above I₂ are limited and do not reach the superconductive device connected to the lead of the present invention. By choosing the appropriate structure (geometry and/or material) for the distal section, the value of I₂ can be adjusted to a desired current. In a two-section current limiting lead of the present invention, once the current passing through the lead reaches I₂, the distal section is quenched and may heat a portion of the proximal section to a temperature Tₓ. Consequently, the rise in temperature may reduce the working current of the proximal section, to Iₓ (following curve 520a). Even in these conditions, because Iₓ is larger than I₁, and therefore considerably larger than I₂, the heat resulting from the quenching of the distal section of the lead will not be likely to cause the quenching of the proximal section. Even if the heat generated by the distal section's quenching is so high that a portion of the proximal section is heated to the maximal temperature of the high temperature range (77K, in this example), the working current of the proximal section would only fall to I₂. Since I₂ is still considerably larger than I₁, the quenching of the proximal section will be unlikely. In fact, by choosing the right materials and geometries of the distal and proximal sections, it can be ensured that the quenching of the distal section will cause the current passage through the lead to stop (in the manners described above), before it can bring about a quenching of the proximal section and of the superconducting device.

Referring to FIG. 7, an embodiment of the present invention is illustrated in which the proximal section 504 of the current limiting superconductive current lead 500 is made of a superconductor layer 318 on a dielectric substrate 316. The proximal section 504 may sport the characteristics of the proximal section 310 described above with reference to FIGS. 3-4d. In a preferred embodiment, the superconductor layer 318 is covered by a metallic layer having a moderate resistance, as described with reference to FIG. 4a. As explained above, such resistive metallic layer would increase the current limiting properties of the lead 500. The distal section 502 may be any superconducting lead, as long as it sports a working current considerably lower than the value that the working current of the proximal section 504 would assume at the same temperature or temperature range of the distal section 502. For example, the distal section 502 may be a superconductor-on-metal lead as described above, such as a 2G HTS. In this manner, the current lead 500 is a current limiter and possesses decreased heat conductivity, as described with reference to the current lead 300 of FIG. 3.

Referring to FIG. 8, an embodiment of the present invention in which the current limiting superconductive current lead 500 includes two different superconductor layers 520 and 318 located on the dielectric substrates 522 and 316, respectfully. The distal section 502 includes a first superconductor layer 520 located on a first dielectric substrate 522, while the proximal section includes a second superconductor layer 318 located on a first dielectric substrate 316. Optionally, the dielectric substrates 522 and 316 are part of a common dielectric structure. The working current of the distal superconductor layer 520 is substantially lower than the value that the working current of the proximal superconductor layer 318 would assume at the same temperature or temperature range of the distal superconductor layer 520. This may be achieved by the proper selection of two different superconductors forming the first superconductor layer 520 and the second superconductor layer 318. For example, the superconductor layers 520 and 318 may have the same cross sectional area, but different critical current densities (i.e., the distal superconductor layer 520 having a critical current density higher than that of the proximal superconductor layer 318). The superconductor-on-dielectric sections 502 and 504 may sport the characteristics of any superconductor-on-dielectric sections described above with reference to FIGS. 3-4b.

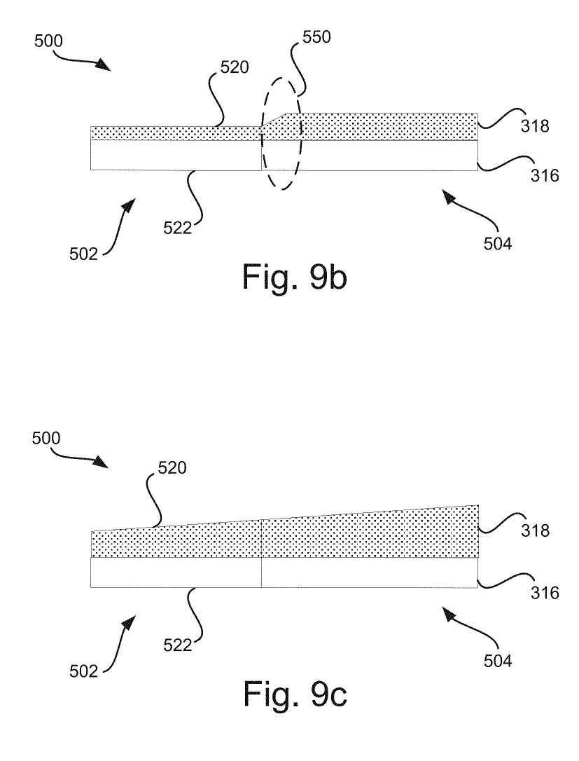

Referring to FIGS. 9a-9c, an embodiment of the present invention is illustrated, in which the current limiting superconductive current lead 500 includes a proximal dielectric substrate 522 being covered by a relatively thick layer of a superconductor and a distal dielectric substrate 316 covered by a relatively thin layer of the same superconductor. As explained above, the critical current (and therefore the working current for a given temperature) of superconductor is a growing function of the cross section of the superconductor. Therefore, for the same width, a thicker superconductor layer 318 has a larger working current than that of a thinner superconductor layer 520, for the same temperature or temperature range. As indicated above, the dielectric substrates 522 and 316 are constituted by a common dielectric structure.

In the example of FIG. 9a, the distal superconductor layer 520 and the proximal superconductor layer 318 each have a uniform thickness. The meeting point between the distal superconductor layer 520 and the proximal superconductor layer 318 features a discontinuity of superconductor layer thickness along the length of the lead 500. According to a non-limiting example, the thick superconductor layer 318 is 1 μm-thick superconducting YBCO, while the thin superconductor layer 520 is 600 nm-thick, or 800 nm-thick superconducting YBCO.

In the example of FIG. 9b, the superconductor layer thickness changes gradually along the length of the lead 500. The proximal superconductor layer 318 has an intermediate region 550 in which the superconductor layer thickness rises in a continuous fashion from the thickness of the distal superconductor layer 520 to the largest thickness of the superconductor layer 318. In the example illustrated in FIG. 9b, the rise of the superconductor layer thickness in the intermediate region 550 is linear. However, such rise may be in any other continuous manner (for example, resembling a parabola, an arc, or a curve).

In the example of FIG. 9c, the superconductor layer thickness changes gradually along the whole length of the lead 500. As we travel from a distal end of the lead 500 to a proximal end thereof, the thickness of the superconductor layer rises gradually (and optionally continuously) between a minimal value at the distal end and a maximal value at the proximal end. The rise may be linear or in any other continuous form (for example, resembling a parabola, an arc, or a curve). Optionally, the rise is continuous in one or more portions of the lead 500, and non-continuous in one or more other portions thereof.

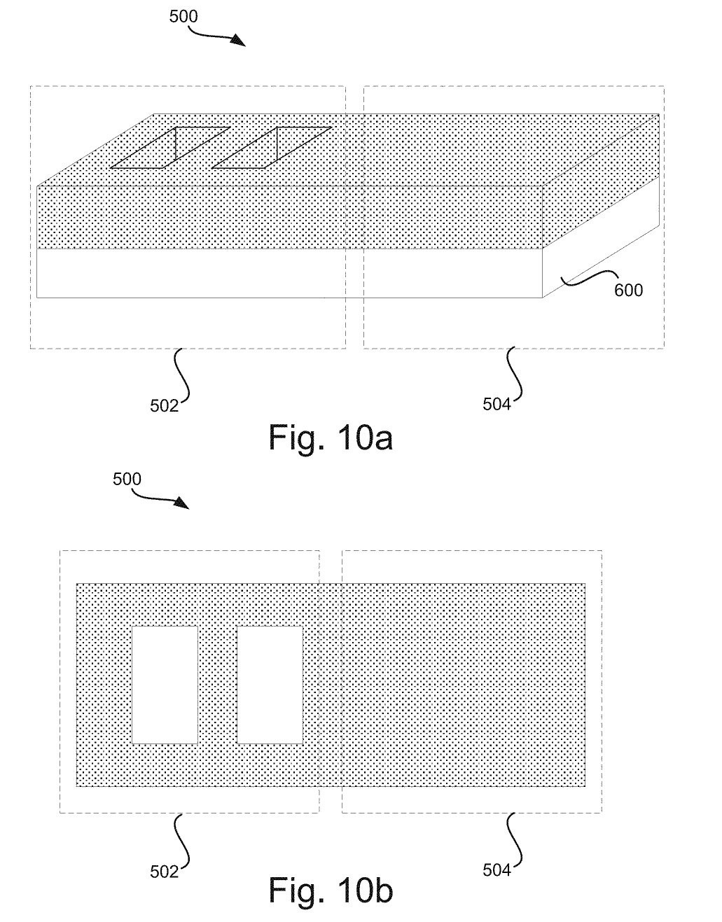

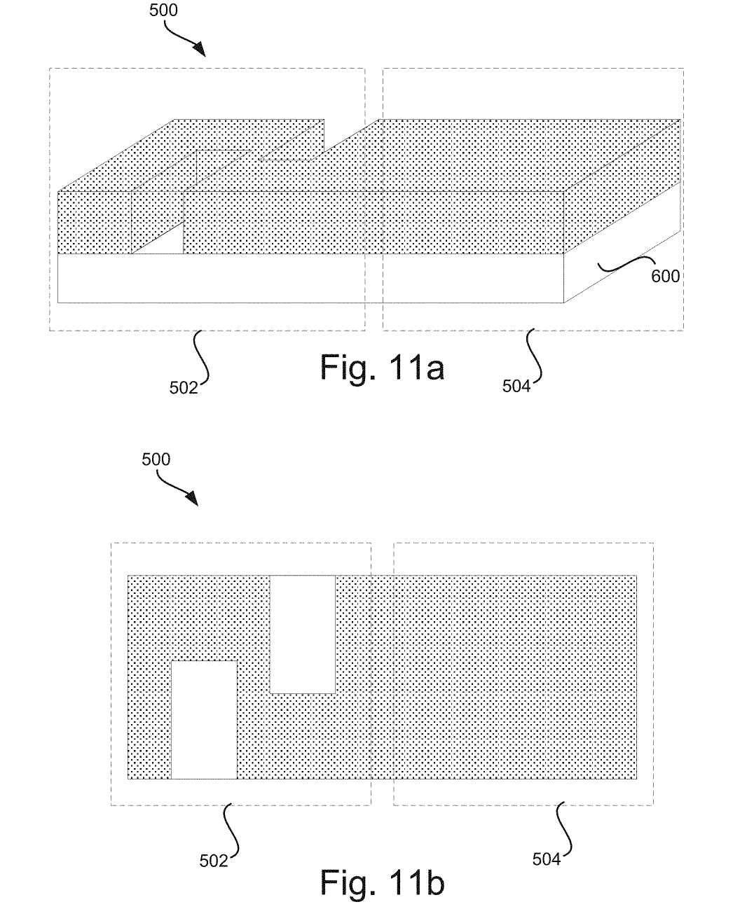

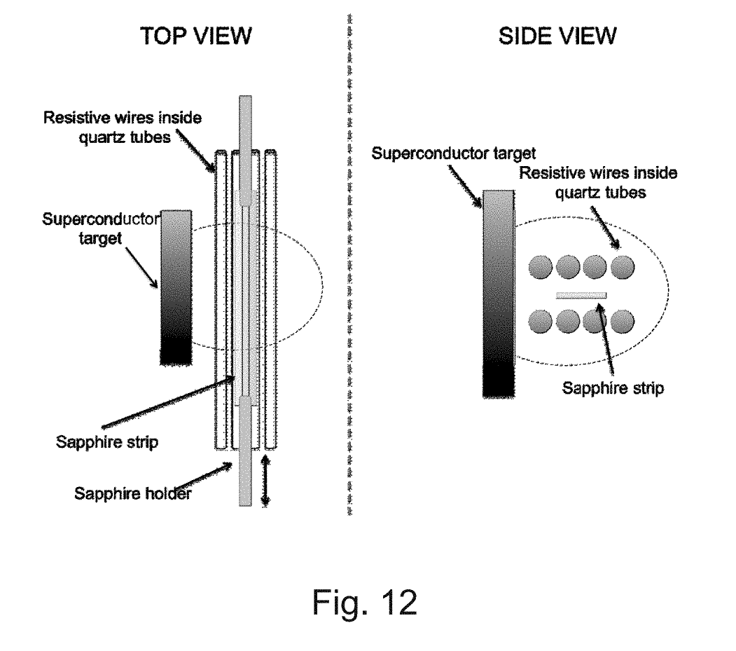

FIGS. 10a-11b are schematic drawings illustrating different views of a current limiting superconductive current lead of yet a further example. Here, a dielectric substrate 600 is covered by a superconductor layer, and a part of the superconductor layer is patterned, thereby forming a distal section having a decreased working current as compared to the working current of remaining part of the superconductor layer at the temperature or temperature range of the patterned section. In the example of FIGS. 10a-10b showing respectively a perspective view and a top view of the current limiting superconductive current lead, the pattern is in the form of a single opening or an array of spaced-apart openings (2 openings in the present example) surrounded by the superconductive material. In the example of FIGS. 11a-11b, the pattern is in the form of spaced-apart side recesses. The provision of a pattern in one section while keeping the material continuity of the other section results in different cross sections along the lead and accordingly in different values of working current at different sections of the lead, for the same temperature or temperature range.

The combination of a thin superconductor layer on a dielectric substrate (e.g. YBCO/YSZ/sapphire) allows for a complicated patterning using standard lithography procedures. As an example, one could integrate a fault current limiter (FCL) element as a part of the current lead. In the distal section 502 of the current lead 500, the superconductor layer is patterned to have one or more regions of decreased width, and therefore has a lower working current than the unpatterned superconductor in the proximal section 504 of the current lead 500, for the same temperature. It is possible to tailor the pattern so that above a given current only the distal section 502 of the lead would become resistive, thus limiting the current from further increasing. Moreover, integrating such limiting elements in the high temperature section of the current leads (i.e. the distal section 502), outside the liquid helium of a cryogenic system, reduces the risks of evaporating large amounts of liquid helium in a violent quench.

As indicated above, in the device of the present invention, a superconducting layer is located on a dielectric substrate. FIG. 12 exemplifies a process suitable to be used in the invention for manufacturing such dielectric-superconductor structure. This figure describes a heating/sputtering apparatus used to coat a dielectric strip (e.g. sapphire) with a superconducting layer from both sides. Atoms dislodge from the superconducting target (so called sputtering process) onto the heated substrate. The dielectric substrate is heated by contact with at least one row of heating tubes. In order to coat the dielectric substrate on both sides thereof with the superconductor, the dielectric substrate is placed between two rows of heating tube (or in any other closed configuration), and rotated together with the rows do heating tubes. The tubes are spaced apart from each other (approximately one diameter apart) so that the sputtered atoms are able to reach the substrate. Optionally, the tubes are quartz tubes having resistive wires passing therethrough, the quartz being heated by electrical current passing through the resistive wires. Though the example illustrated in FIG. 12 relates to sputtering, the process of placing atoms of superconducting material onto the heated substrate (i.e. the process of coating) may be achieved by laser ablation or chemical vapor deposition (CVD).

Referring now to FIG. 13, there is illustrated an exemplary set-up for connecting a copper lead to the proximal section 310. Electrical connection of the proximal section 310 to the superconductive device 304 may mediated via a copper lead 700. One side of the copper lead is connected to the metallic layer 404 and the other side of the copper lead 700 is connected to the superconductive device 304. The connection between the copper lead 700 and the metallic layer 404 may be achieved by pressing a thin metallic foil 702 between the copper lead 700 and the metallic layer 404. The metallic foil 702 may be, for example, made of copper or indium. Using this technique, contact resistance (resistance at the contact point between the copper lead and the metallic layer 404) as low as 1.6 μΩcm² at 77K have been achieved, better than commercial HTS current leads −2 μΩcm².

1. A superconducting lead for conducting electrical current to a superconducting device, the lead comprising first and second sections arranged one after the other along the lead, such that when the lead is brought to the superconducting device, said first and second sections are respectively proximal and distal sections with respect to the superconducting device, said proximal and distal sections being configured such that they differ from one another in at least one of heat conductance and working current.

2. The superconducting lead of claim 1, wherein said first section has lower heat conductance than said second section at relatively low temperatures; and said second section has a lower heat conductance than said first section at relatively high temperatures.

3. The superconducting lead of claim 2, wherein said relatively low temperatures include temperatures approaching 4.2K, and said relatively high temperatures include temperatures approaching 77K.

4. The superconducting lead of claim 1, having at least one of the following configurations: (i) said first section comprises a dielectric substrate coated on at least one side by a first superconductor film; (ii) said second section comprises a conductive metallic substrate coated by a second superconductor layer; and (iii) said first section comprises a superconductive compound of the formula YBa₂Cu₃O₇₋ₓ (YBCO).

5. The superconducting lead of claim 3, wherein at a temperature Tᵢ, the heat conductance of said first section is equal to the heat conductance of the second section, such that said first section has lower heat conductance than said second section at temperatures in the range between 4.2K and Tᵢ, and said second section has a lower heat conductance than said first section at temperatures in the range between Tᵢ and 77K, Tᵢ being in the range 4.2K≤Tᵢ≤77K.

6. The superconducting lead of claim 5, wherein Tᵢ is within a range between 40K and 50K.

7. The superconducting lead of claim 4, wherein said dielectric substrate of said first section is made of sapphire.

8. The superconducting lead of claim 4, wherein said first section comprises a superconductive YBCO film on a sapphire substrate.

9. The superconducting lead of claim 1, having at least one of the following configurations: said second section comprises a lead section based on a second generation high-temperature-superconductor (2G HTS) wire or tape; and said second section comprises a powder of superconductive material in a tube, said tube having at least a metallic strand.

10. The superconducting lead of claim 6, wherein said second section comprises a powder of superconductive material in a tube, said tube having at least a metallic strand.

11. The superconducting lead of claim 1, having at least one of the following configurations: (a) said first section further comprises a buffer layer between a dielectric substrate and a superconductor film, said buffer layer being configured to decrease or prevent the diffusion rate of atoms from said substrate to the superconductor film; (b) said first section comprises a dielectric substrate carrying a non-superconductive template layer, and a superconductor film on top of the template layer; (c) said first section comprises an Yttrium-stabilized-Zirconia (YSZ) buffer layer between a substrate and a superconductive YBCO film, said buffer layer being configured to decrease or prevent diffusion rate of atoms from said substrate to the superconductive YBCO film; and (d) said first section comprises a dielectric substrate, a template layer of non-superconductive YBCO, and a YBCO superconductive film on said template layer.

12. The superconducting lead of claim 4, wherein a combination of said superconductor and said dielectric substrate includes one of the following: YBa₂Cu₃O₇₋ₓ layer on a LaAlO₃ substrate; YBa₂Cu₃O₇₋ₓ layer on a SrTiO₃ substrate; YBa₂Cu₃O₇₋ₓ layer on a YSZ substrate; YBa₂Cu₃O₇₋ₓ layer, YSZ buffer, and Sapphire substrate; YBa₂Cu₃O₇₋ₓ layer, YSZ buffer, and Si substrate; Tl₂Ba₂CaCu₂O₈ layer on SrTiO₃ substrate.

13. The superconducting lead of claim 4, wherein said first section comprises a metallic layer deposited on the superconductor film.

14. The superconducting lead of claim 13, wherein said metallic layer is made of one of the following: gold, silver, and gold-silver alloy.

15. The superconducting lead of claim 4, having at least one of the following configurations: said dielectric substrate is coated on two opposing surfaces thereof by films of said superconductor; and said dielectric substrate is a dielectric wire and is coated by said superconductor film on at least two opposite sides or on at least one side of said dielectric wire.

16. The superconducting lead of claim 4, wherein said first section of the lead comprises a stack comprising individual strips, each strip comprising said dielectric substrate coated on opposing surfaces thereof by said superconductor film, said blocks being connected in parallel, such that said dielectric surfaces do not touch each other.

17. The superconducting lead of claim 1, wherein said second section has working current lower than a working current that said first section would support if said first section were at the same temperature or temperature range of said second section, thereby limiting a maximal current flow through the lead when the lead is in a superconducting state.

18. The superconducting lead of claim 17, having at least one of the following configurations: (1) the first and second sections have different material compositions defining said different working current values; (2) the second section is patterned to reduce its working current relative to the working current that the first section would assume if it were at the same temperature or temperature range as the second section; (3) said first section comprises a first dielectric substrate coated on at least one side by a first superconductor film; and (4) the second section comprises a second dielectric substrate coated on at least one side by a second superconductor film, said second superconductor film having a working current that is lower than the working current that said first superconductor film would have if said first second superconductor film were at the same temperature or temperature range as the second superconductor film.

19. A method for manufacturing a structure having a dielectric substrate covered by a superconductor layer, the method comprising:
heating the dielectric substrate by placing the dielectric substrate on a row of spaced-apart heated tubes; and
coating at least one surface of the dielectric substrate with the superconductor layer.

20. The method of claim 19, characterized by at least one of the following: heating the dielectric substrate is achieved by placing the dielectric substrate between two row of spaced-apart heated tubes, the method further comprising rotating the dielectric substrate and said rows of tubes such that the superconductor material reaches the dielectric substrate via spaces between said spaced-apart tubes; and the coating is achieved by one of: sputtering, laser ablation, and chemical vapor deposition.
